(19) United States
(12) Patent Application Publication
(10) Pub. No.: US 2025/0208502 A1
(43) Pub. Date: Jun. 26, 2025

(54) STAMPS FOR MICRO-TRANSFER-PRINTING WITH CURVED STAMP POST ENDS

(71) Applicant: X-Celeprint Limited, Dublin (IE)

(72) Inventors: Ronald S. Cok, Rochester, NY (US); Raja Fazan Gul, Cork (IE)

(21) Appl. No.: 18/989,413

(22) Filed: Dec. 20, 2024

Related U.S. Application Data
(60) Provisional application No. 63/619,987, filed on Jan. 11, 2024.
(60) Provisional application No. 63/613,999, filed on Dec. 22, 2023.

(51) Int. Cl. G03F 7/00

(52) U.S. Cl. CPC G03F 7/0002; G03F 7/0015

(57) ABSTRACT

A micro-transfer-printing stamp includes a rigid support and an array of posts disposed over the rigid support. Each of the posts can extend in a direction away from the rigid support to a distal surface of the post. The distal surface of each post can be substantially convex with a center farther from the rigid support than another portion of the distal surface. The convex surface can be structured to contact a component when the distal surface is pressed against the component. The distal surface of each post in the array of posts can be substantially concave with a center closer to the rigid support than another portion of the distal surface. The concave surface can be structured to contact a component when the distal surface is pressed against the component. Each of the posts can comprise an elastic material.

### CROSS REFERENCE TO RELATED APPLICATIONS

This application claims priority to U.S. Provisional Application No. 63/613,999, filed Dec. 22, 2023, and U.S. Provisional Application No. 63/619,987, filed Jan. 11, 2024, the disclosure of each of which is incorporated by reference herein in its entirety.

### TECHNICAL FIELD

The present disclosure generally relates to micro-transfer printing stamps and stamp structures.

### BACKGROUND

Substrates with electronically active components distributed over the extent of the substrate are used in a variety of electronic systems, for example, in flat-panel display components such as flat-panel liquid crystal or organic light emitting diode (OLED) displays, in imaging sensors, and in flat-panel solar cells. The electronically active components are typically either assembled on the substrate, for example using individually packaged surface-mount integrated-circuit components and pick-and-place tools, or by coating a layer of semiconductor material on the substrate and then photolithographically processing the semiconductor material to form thin-film circuits on the substrate. Individually packaged integrated-circuit components typically have smaller transistors with higher performance than thin-film circuits but the packages are larger than can be desired for highly integrated systems.

Methods for transferring small, active components from one substrate to another are described in U.S. Pat. Nos. 7,943,491, 8,039,847, and 7,622,367. In some such approaches, small integrated circuits are formed on a native semiconductor source wafer. The small, unpackaged integrated circuits, or chiplets, are released from the native source wafer by pattern-wise etching portions of a sacrificial layer located beneath the chiplets, leaving each chiplet suspended over an etched sacrificial layer portion by a tether physically connecting the chiplet to an anchor separating the etched sacrificial layer portions. A viscoelastic stamp is pressed against the process side of the chiplets on the native source wafer, adhering each chiplet to an individual stamp post. The stamp with the adhered chiplets is removed from the native source wafer. The chiplets on the stamp posts are then pressed against a non-native target substrate or backplane with the stamp and adhered to the target substrate.

In another example, U.S. Pat. No. 8,722,458 entitled Optical Systems Fabricated by Printing-Based Assembly teaches transferring light-emitting, light-sensing, or light-collecting semiconductor elements from a wafer substrate to a destination substrate or backplane. Such micro-transferred components can provide the high performance of crystalline semiconductor components together with the small size of unpackaged dies.

Micro-transfer printing stamps are an important part of any micro-transfer printing system and method. Typically, each stamp comprises an array of individual stamp posts and each stamp post contacts a component (e.g., chiplet) during printing. The structure of the stamp post can affect the component pickup from a source wafer and the component printing to a target substrate. In some designs, the distal end of each individual stamp post is flat. In other designs, the distal end of each individual stamp post is structured. For example, U.S. Pat. No. 9,412,727 discloses a stamp with micro-tips in a three-dimensional relief pattern. There is an ongoing need, therefore, for stamp structures that are highly reliable and easy-to-use for a variety of component micro-transfer printing processes.

### SUMMARY

The present disclosure provides, inter alia, structures and methods for more efficiently micro-transfer printing components (e.g., devices) from a component (or device) source wafer to a target substrate with improved yields. According to embodiments of the present disclosure, a micro-transfer-printing stamp comprises a rigid support and an array of posts disposed over the rigid support (e.g., and directly on the rigid support or with a mesa disposed therebetween). Each of the posts in the array of posts can extend in a direction away from the rigid support to a distal surface of the post. In some embodiments, the distal surface of each post in the array of posts is substantially convex with a center farther from the rigid support than another portion of the distal surface. The convex surface can be structured to contact a component (e.g., a device, structure, or material) when the distal surface is pressed against the component. In some embodiments, the distal surface of each post in the array of posts is substantially concave with a center closer to the rigid support than another portion of the distal surface. The concave surface can be structured to contact a component when the distal surface is pressed against the component. Each of the posts can comprise an elastic material.

In some embodiments, the posts in the array of posts can comprise an elastomeric material. In some embodiments, the posts in the array of posts can comprise PDMS. In some embodiments, the distal surface of each of the posts is continuously curved. In some embodiments, the radius of curvature of the distal surface decreases from the center to the edge so that the curvature increases toward the edge and decreases toward the center. In some embodiments, the radius of curvature of the distal surface is constant. In some embodiments, the distal surface is stepped.

In some embodiments, a portion of the distal surface is flat. In some embodiments, the portion that is flat includes the center or forms a perimeter around the center. In some embodiments, the portion that is flat is a simple closed curve. In some embodiments, a portion of the distal surface that is not flat is curved and has a constant or decreasing radius of curvature in a direction from the center to an edge of the stamp post.

According to some embodiments of the present disclosure, a micro-transfer-printing stamp comprises a mesa disposed on the rigid support between the rigid support and the stamp posts, and the stamp posts extend from the mesa in a direction away from the rigid substrate.

According to some embodiments of the present disclosure, a center of the distal surface is surrounded by portions of the distal surface that have a different distance from the rigid support than a distance from the center to the rigid support.

In some embodiments of the present disclosure, a component having a component surface is in contact with the distal surface of a post (e.g., one of the stamp posts), the post is under compression, and all of the distal surface is in contact with the component surface. In some embodiments of the present disclosure, a component having a component surface is in contact with the distal surface of a post (e.g., one of the stamp posts), the post is under compression, and less than all of the distal surface is in contact with the component surface. Some embodiments comprise a component source wafer and the component is connected to the component source wafer, for example with a tether connected to an anchor portion of the component source wafer.

Some embodiments comprise a target substrate having a target substrate surface and the component is in contact with the target substrate surface on a surface of the component opposite the component surface.

According to some embodiments, the distal surface of the stamp post is concave or convex in one dimension. According to some embodiments, the distal surface of the stamp post is concave or convex in two dimensions.

According to some embodiments, a method of assembling a component can comprise providing a component source substrate with a component having a component surface connected to the component source substrate, providing a micro-transfer-printing stamp, pressing a post of the stamp against the component surface with the transfer printer so that the component is adhered to a first area of the concave surface, relaxing the compressed post so that the component is adhered to the post with a second area of the distal surface less than the first area, removing the component from the component source substrate by moving the stamp away from the component source substrate with the transfer printer, transporting the stamp and component to a target substrate having a target substrate surface with the transfer printer, and pressing the component against the target substrate surface with the printer so that the component is adhered to the target substrate surface and the component is adhered to the post with a third area of the concave surface less than the first area with the transfer printer. The third area can be no less than the second area. Some methods of the present disclosure comprise removing the post from the component.

In some embodiments, a method of making a micro-transfer-printing stamp mold can comprise providing a base, coating the base with a curable material (e.g., a polymer, such as an acrylic), pattern-wise curing the curable material to form a patterned structure (e.g., a mold pattern) comprising a cured material [e.g., wherein the patterned structure comprises periodically spaced features each with a curved end (e.g., a one-dimensionally curved end or a two-dimensionally curved end)], and removing any uncured curable material to form a stamp mold. Further embodiments can comprise coating the stamp mold with an uncured curable stamp material (e.g., PDMS), curing the stamp material, and removing the stamp from the stamp mold. The stamp mold can be coated with a delamination enhancement material (e.g., an inorganic material, such as SiO₂, or a metal to which PDMS does not adhere well) to enhance delamination of the stamp from the stamp mold and enable peeling the stamp out of or from the stamp mold. Some embodiments further comprise contacting a printable component on a component source wafer with the stamp, removing the component from the component source wafer, transporting the removed component to a target substrate, and printing the component onto the target substrate.

In some embodiments, a method of making a micro-transfer-printing stamp mold, comprises providing a base, coating the base with a curable material (e.g., a polymer, such as an acrylic), optionally coating a thin delamination enhancement layer, and forming a patterned structure (e.g., a mold pattern) comprising a cured material from the curable material. The patterned structure can comprise periodically spaced features each with a curved end (e.g., a one-dimensionally curved end or a two-dimensionally curved end). The method can comprise removing any uncured curable material to form a stamp mold. In some embodiments, the method comprises treating or coating a surface of the patterned structure in order to reduce adhesion to a stamp during stamp fabrication (e.g., comprising fluorinating the surface). In some embodiments, the method comprises 3D printing the patterned structure. In some embodiments, the method comprises using two-photon polymerization to form the patterned structure. In some embodiments, the method comprises pattern-wise curing the curable material to form the patterned structure. The curved end can contact the base. In some embodiments, the curved end does not contact the base. The curable material can have a cure temperature that is higher than a cure temperature of a curable stamp material for the stamp (e.g., PDMS). The curable material can have a cure temperature that is higher than a cure temperature of PDMS. Some embodiments can comprise coating the stamp mold with an uncured curable stamp material (e.g., PDMS), curing the stamp material, and removing the stamp from the stamp mold. The curable material can have a cure temperature that is higher than a cure temperature of the curable stamp material.

In some embodiments, a micro-transfer-printing stamp mold can comprise a cured polymer defining a patterned structure, (e.g., a cured acrylic polymer) with the patterned structure comprising periodically spaced features each with a curved end. The features can correspond to stamp posts of the stamp. The features can have one-dimensional curvature. The features can have two-dimensional curvature. The patterned structure can be treated or coated to reduce adhesion (e.g., can be fluorinated). The patterned structure can have a higher cure temperature than a cure temperature of a curable material (e.g., a PDMS) for the stamp. The patterned structure can have a higher cure temperature than a cure temperature of PDMS.

Structures and methods described herein enable stamp structures and a release and printing process for micro-transfer printing components from a source wafer to a target substrate having improved yields and reliability.

### BRIEF DESCRIPTION OF THE DRAWINGS

The foregoing and other objects, aspects, features, and advantages of the present disclosure will become more apparent and better understood by referring to the following description taken in conjunction with the accompanying drawings, in which:

FIG. 1 is a perspective and cross-section detail of a stamp with posts having a convex distal surface according to illustrative embodiments of the present disclosure;

FIG. 2 is a perspective and cross-section detail of a stamp with posts having a concave distal surface according to illustrative embodiments of the present disclosure;

FIGS. 3A and 3B are perspectives of convex distal ends of posts in two and one dimensions, respectively, according to illustrative embodiments of the present disclosure;

FIGS. 4A and 4B are perspectives of concave distal ends of posts in two and one dimensions, respectively, according to illustrative embodiments of the present disclosure;

FIGS. 5A and 5B are cross sections of concave and convex distal ends of posts, respectively, having a flat area in the center of the distal end according to illustrative embodiments of the present disclosure;

FIGS. 6A and 6B are cross sections of concave and convex distal ends of posts, respectively, having a flat area around a perimeter of the distal end according to illustrative embodiments of the present disclosure;

FIG. 6C is a cross section of a convex distal end of a post having a variable radius of curvature according to illustrative embodiments of the present disclosure;

FIG. 7 is a perspective of a concave distal end of a post having a flat perimeter according to illustrative embodiments of the present disclosure;

FIGS. 8A-8E are successive cross sections of a stamp post contacting a component using overdrive according to illustrative embodiments of the present disclosure;

FIG. 9 is a cross section of a stamp and post contacting a component suspended by a tether over a sacrificial portion of a source wafer according to illustrative embodiments of the present disclosure;

FIGS. 10A-10F are successive cross sections of a stamp post with an adhered component removed from a source substrate and printed to a target substrate according to illustrative embodiments of the present disclosure;

FIG. 11 is a flow diagram of micro-transfer printing according to illustrative embodiments of the present disclosure;

FIGS. 12A-12G are successive cross sections of steps in constructing a stamp mold according to illustrative embodiments of the present disclosure;

FIG. 13 is a micrograph of a cavity suitable for making a stamp mold according to illustrative embodiments of the present disclosure;

FIGS. 14A-14C are successive cross sections of steps in constructing a stamp using the stamp mold according to illustrative embodiments of the present disclosure;

FIGS. 15A-15E are successive cross sections of steps in constructing a stamp using 3D printing according to illustrative embodiments of the present disclosure;

FIG. 16 is a flow diagram of making a mold using 3D printing according to illustrative embodiments of the present disclosure; and

FIG. 17 is a perspective of a stamp post having steps according to illustrative embodiments of the present disclosure.

Features and advantages of the present disclosure will become more apparent from the detailed description set forth below when taken in conjunction with the drawings, in which like reference characters identify corresponding elements throughout.

In the drawings, like reference numbers generally indicate identical, functionally similar, and/or structurally similar elements. The figures are not drawn to scale since the variation in size of various elements in the Figures is too great to permit depiction to scale.

### DETAILED DESCRIPTION OF CERTAIN EMBODIMENTS

The present disclosure provides, inter alia, structures and methods for micro-transfer printing components (e.g., devices) from a component (or device) source substrate to a target substrate. Embodiments of the present disclosure provide stamps that can pick up components from the component source wafer and print the components to the target substrate with improved yields for a greater variety of components under a greater variety of process, target substrate, and material conditions.

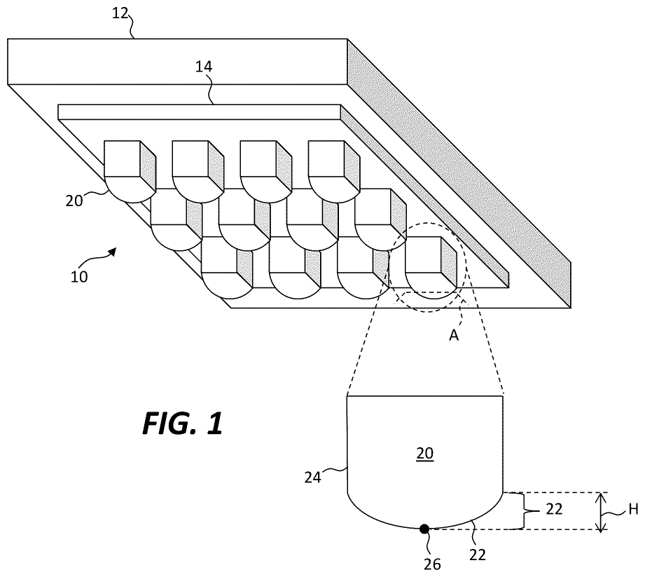

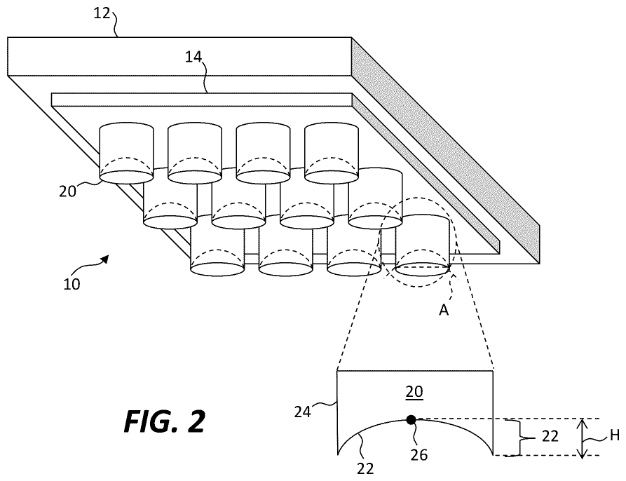

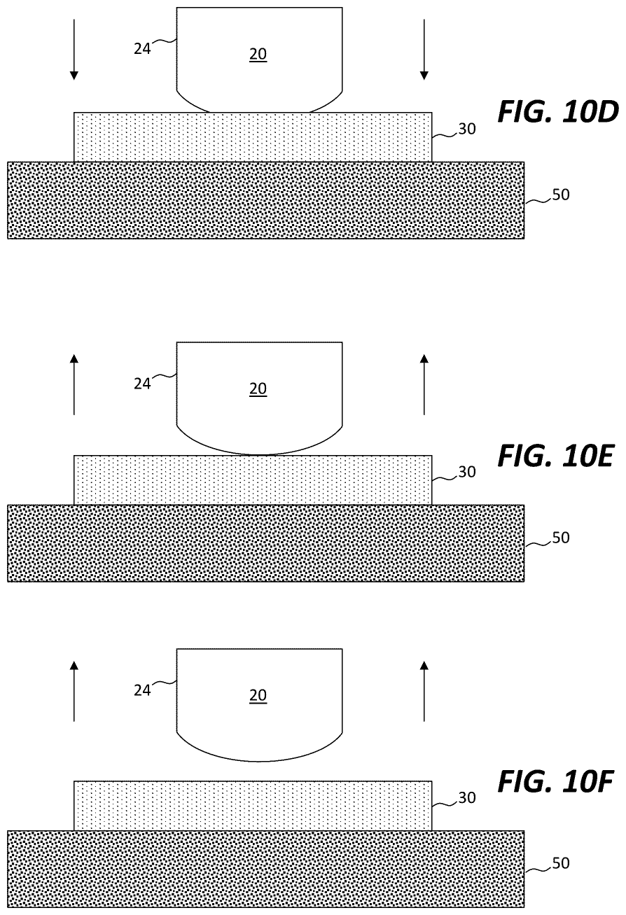

According to some embodiments of the present disclosure and as shown in FIGS. 1 and 2, a micro-transfer-printing stamp 10 can comprise a rigid support 12 and an array of posts 20 (stamp posts 20) disposed over rigid support 12 (e.g., and directly on rigid support 12 or with mesa 14 disposed therebetween). Each stamp post 20 can comprise an elastic material, e.g., a visco-elastic or elastomeric material, such as polydimethylsiloxane (PDMS), having rate-dependent adhesion. Each of stamp posts 20 in the array of posts 20 can extend in a direction away from rigid support 12 (e.g., orthogonally) to a distal surface 22 (a distal end 22 of stamp posts 20). Distal end 22 is at an opposite end of a proximal end of stamp post 20 disposed adjacent to or in contact with rigid support 12 or a mesa 14 on rigid support 12. In embodiments, mesa 14 can be a bulk layer or pedestal disposed on (e.g., directly on) rigid support 12 and stamp posts 20 are disposed on (e.g., directly on) mesa 14 with a proximal end of stamp posts 20 in direct contact with mesa 14 and distal end 22 of stamp posts 20 on an opposite end of stamp posts 20 from the proximal end. In embodiments, stamp posts 20 (and optionally mesa 14) are flexible and elastic so that they can be deformed by pressure without breaking and can return to their original shape when the pressure is removed. Stamp posts 20 (and optionally mesa 14) can be more flexible than rigid support 12. Distal surface 22 can be that portion of stamp post 20 structured to contact a surface of a component 30 when stamp post 20 is pressed against component 30 without stamp post 20 collapse (e.g., without stamp post 20 bending although stamp post 20 can bulge outward when compressed as shown in FIG. 8E discussed below). In some embodiments, each component 30 being printed contacts only one stamp post 20. Not every stamp post 20 need pick up or need print a component 30 during a print operation.

In some embodiments and as shown in FIG. 1, distal surface 22 of each stamp post 20 in the array of posts 20 can be substantially convex or have a substantially convex shape with a height H and center 26 farther from rigid support 12 than another portion of distal surface 22 or than a stamp post edge 24 (e.g., sidewall(s) 24) of stamp post 20. The convex shape can be at least partially curved or entirely curved. The convex surface can be structured to contact a component 30 (as described below with respect to FIGS. 8A-8E) when distal surface 22 of stamp post 20 is pressed against component 30 so that at least a portion of stamp post 20 is compressed. A central portion of distal surface 22 can be compressed more than portions of stamp distal surface 22 that are not at center 26 of distal surface 22, e.g., compressed more than a perimeter portion of distal surface 22 closer to sidewall(s) 24 than to center 26.

In some embodiments and as shown in FIG. 2, distal surface 22 of each stamp post 20 in the array of posts 20 can be substantially concave or have a substantially concave shape with a center 26 closer to rigid support 12 than another portion of distal surface 22 or than a stamp post edge 24 (e.g., sidewall(s) 24) of stamp post 20. The convex shape can be at least partially curved or entirely curved. The concave surface can be structured to contact a component 30 (as described below with respect to FIGS. 8A-8E) when distal surface 22 of stamp post 20 is pressed against component 30 so that at least a portion of stamp post 20 is compressed. A central portion of distal surface 22 can be compressed less than portions of stamp distal surface 22 that are not at center 26 of distal surface 22, e.g., a perimeter portion of distal surface 22 closer to sidewall(s) 24 than to center 26. In some embodiments of the present disclosure, sidewalls 24 of stamp post 20 that have a vertical surface orthogonal to a surface of rigid support 12 from which mesa 14 or stamp posts 20 extend are not on the end of stamp post 20 and are not a portion of distal surface 22. For example, distal surface 22 can end where sidewalls 24 of stamp post 20 begin.

Stamps 10 can comprise multiple stamp posts 20. Stamp posts 20 can have a variety of aspect ratios, shapes, and sizes (e.g., can vary in area or cross section parallel to a surface on rigid support 12 or mesa 14 from which posts 20 extend). Stamp posts 20 can have a square, rectangular, circular, or oval distal surface 22 or cross section. Stamp posts 20 can have different distributions or spacing over the extent of stamp 10, e.g., over the extent of mesa 14 or rigid support 12. Stamp posts 20 can have a variety of lengths (distance extended from mesa 14 or rigid support 12). Stamp posts 20 in a stamp 10 can be all substantially identical or can vary in size or shape. In some embodiments, stamp posts 20 can have a distal surface 22 that has a smaller area than a proximal surface closer to rigid support 12. A choice of the number of stamp posts 20 with different heights, aspect ratios, and shapes can be a matter of design choice, for example dependent on the size, shape, surface, and material of component 30 and the surface and material of any target substrate 50 to which components 30 are micro-transfer printed, as discussed below. The array of stamp posts 20 can be of any useful size, spacing, and arrangement on rigid support 12. Stamp posts 20 are typically disposed in spatial alignment with a corresponding array of components 30 on a component source wafer 40. Each stamp post 20 can be operable to contact a single component 30 so that each component 30 can adhere to distal surface 22 of stamp post 20.

Rigid support 12 can be any rigid substrate, for example comprising glass, that provides a stable support for mesa 14 and stamp posts 20. Visco-elastic materials exhibit rate-dependent adhesion so that, when in contact with the surface of a component 30 relatively rapid motion away from the component surface provides relatively strong adhesion between the visco-elastic stamp material and the component surface and relatively slow motion away from the component surface provides relatively weak adhesion between the visco-elastic stamp material and the component surface. Mesa 14 can comprise a same stamp material as stamp posts 20 or can comprise a different stamp material. In some embodiments, mesa 14 comprises the same stamp materials as stamp posts 20 but in different concentrations and can have a different Young's modulus than stamp posts 20. Mesa 14 and stamp posts 20 can be cast as a liquid stamp material on or in a mold in contact with rigid support 12 and then cured and removed from the mold to make stamp 10. The mold can be made using photolithographic methods and materials, for example photolithographic processing of a wafer of silicon, or 3D printing as discussed further below.

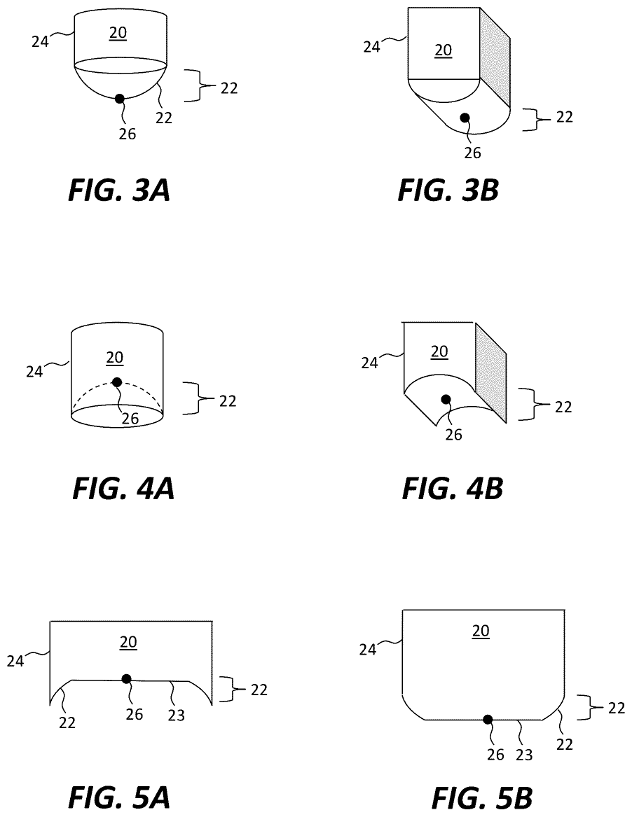

FIG. 3A illustrates embodiments in which distal surface 22 has a convex surface curved in two dimensions, e.g., as with a sphere, ellipsoid, or an oblate solid. In embodiments, distal surface 22 is a hemisphere, a portion of a hemisphere, an ellipsoid, or a portion of an ellipsoid. FIG. 3B illustrates embodiments in which distal surface 22 has a convex surface curved in one dimension, e.g., as with the surface of a cylinder. In embodiments, distal surface 22 has a shape of at least a portion of a cylindrical surface.

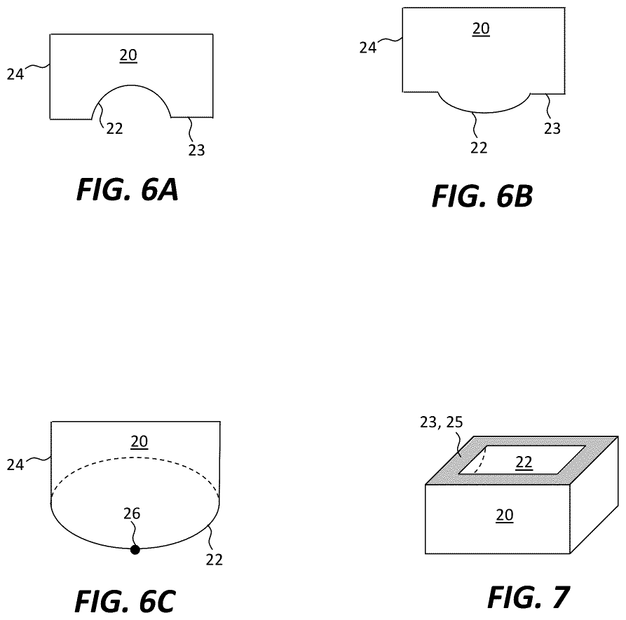

Similarly, FIG. 4A illustrates embodiments in which distal surface 22 has a concave surface curved in two dimensions, e.g., as with a sphere, ellipsoid, or an oblate solid. In embodiments, distal surface 22 is a hemisphere, a portion of a hemisphere, an ellipsoid, or a portion of an ellipsoid. FIG. 4B illustrates embodiments in which distal surface 22 has a concave surface curved in one dimension, e.g., as with the surface of a cylinder. In embodiments, distal surface 22 has a shape of at least a portion of a cylindrical surface.

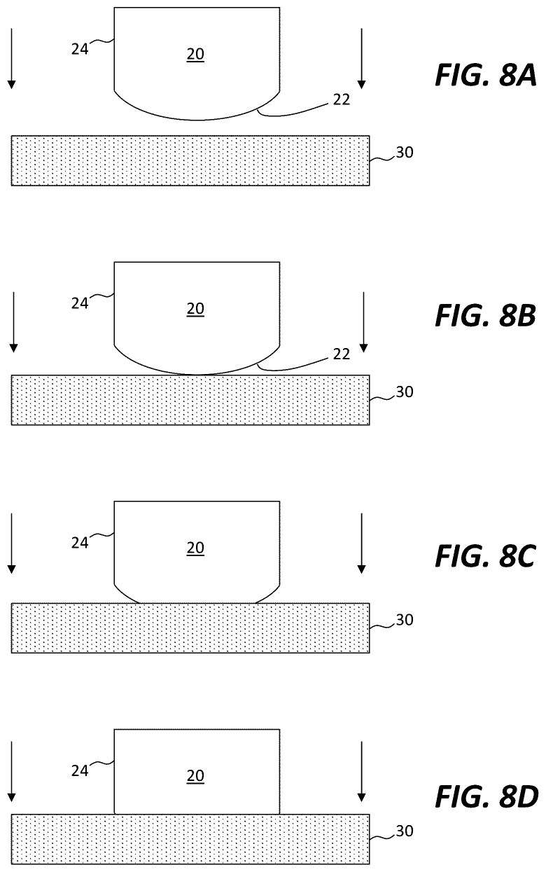

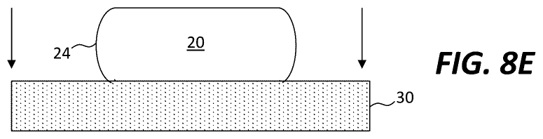

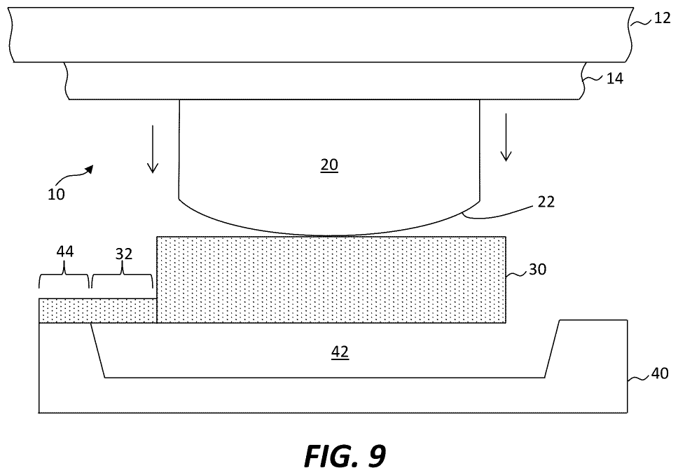

In some embodiments of the present disclosure, distal surface 22 of each stamp post 20 is continuously curved, as shown in FIGS. 1-4B. In some embodiments of the present disclosure, distal surface 22 of each stamp post 20 is discontinuous or has portions that are flat, for example a central flat portion 23 as shown in FIGS. 5A and 5B for concave and convex embodiments, respectively. In some embodiments a perimeter 25 or edge portion of distal surface 22 is flat, as shown in FIGS. 6A and 6B for concave and convex embodiments, respectively. A flat portion 23 of distal surface 22 can be substantially parallel to a surface of rigid support 12 or mesa 14 on which stamp posts 20 are disposed and from which stamp posts 20 extend, e.g., orthogonally. Distal surface 22 can include flat portion 23 and can extend from a sidewall 24 to an opposing sidewall 24 of stamp post 20.

FIG. 6C illustrates embodiments in which distal surface 22 of stamp post 20 is continuously and completely curved and has a variable radius of curvature, for example distal surface 22 can comprise or have a shape of a portion of an ellipse. The radius of curvature can be greatest at center 26 of distal surface 22 so that the central portion of distal surface 22 is flatter than an edge portion of distal surface 22 adjacent to or in contact with sidewall 24. (In FIG. 6C, the dashed line is not a physical structure but is used to illustrate the change in curvature and to show that distal surface 22 is not a sphere or portion of a sphere.) In some other embodiments, distal surface 22 has a constant radius of curvature. In embodiments, those portions of distal surface 22 that are not flat can have a variable or constant radius of curvature.

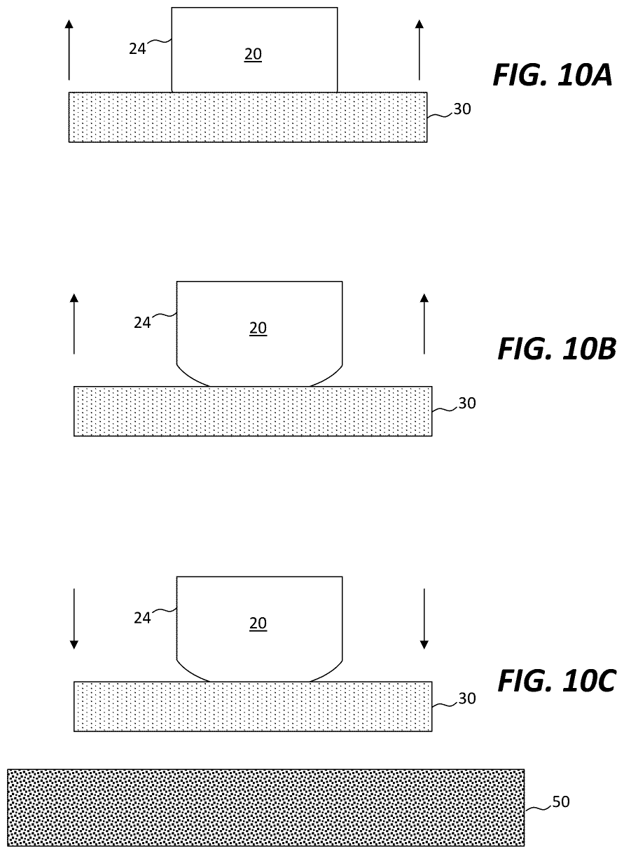

Stamp posts 20 can have a curved, circular, or oval cross section parallel to a surface of rigid support 12 from which mesa 14 or stamp posts 20 extend. In some embodiments, and as shown in FIG. 7, stamp posts 20 can have a rectangular cross section parallel to a surface of rigid support 12 from which mesa 14 or stamp posts 20 extend. Thus, in embodiments, flat portion 23 can form at least a portion of a curved ring or rectangular perimeter 25 surface and a center 26 of distal surface 22 can be surrounded by portions of distal surface 22 that have a different distance from rigid support 12 than a distance of center 26 to rigid support 12.

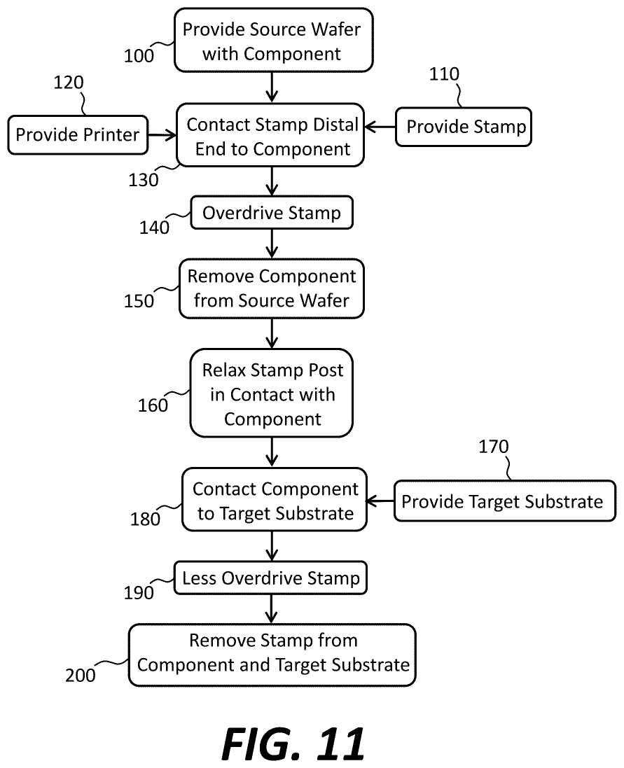

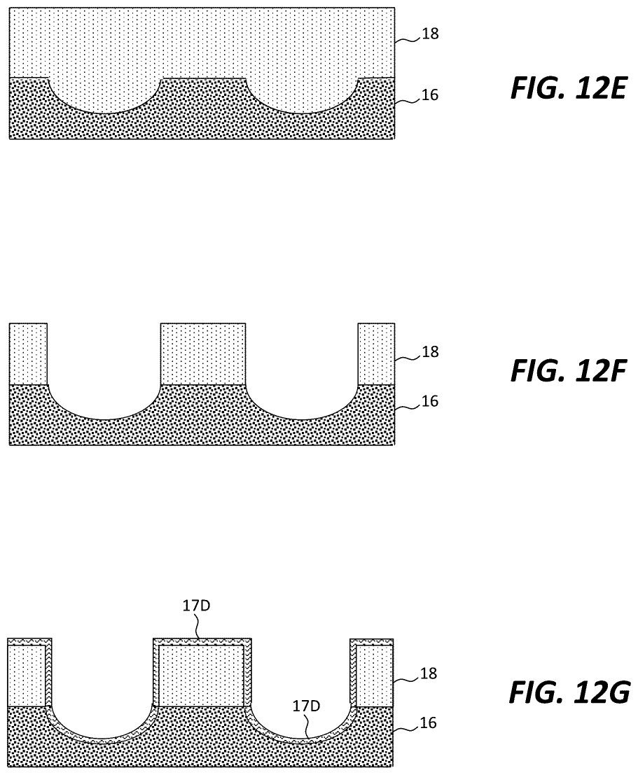

Micro-transfer printing a component 30 from a component source wafer 40 to a target substrate 50 can comprise two operations: removing component 30 from component source wafer 40 (picking) and disposing component 30 on target substrate 50 (printing). FIGS. 8A-8E are successive illustrations of initial picking steps showing a stamp 10 contacting a component 30 with distal surface 22 as described in FIG. 11. As shown in FIG. 8A and FIG. 9, a component source wafer 40 with a component 30 suspended over a sacrificial portion 42 of component source wafer 40 with a tether 32 connected to an anchor 44 portion of component source wafer 40 is provided in step 100. Stamp 10 comprising rigid support 12, mesa 14 disposed on rigid support 12, and a stamp post 20 comprising a convex distal surface 22 (or a concave distal surface 22, not shown in FIG. 8A or 9) disposed on mesa 14 is provided in step 110 and a micro-transfer printer is provided in step 120. In FIG. 9 and FIG. 8B, distal surface 22 (distal end 22) of stamp post 20 contacts a surface of component 30, for example a surface on an opposite side of component 30 from component source wafer 40, in step 130, adhering distal surface 22 and stamp post 20 to component 30, for example using van der Waals forces. Because distal surface 22 is convex (or concave), only a portion of distal surface 22 contacts component 30. In the limit, only a point (for a two-dimensional convex surface) or a line (for a one-dimensional convex surface) contacts component 30. As shown in FIG. 8C, stamp post 20 is pressed farther against component 30 by the printer so that stamp post 20 is compressed and a greater portion of distal surface 22 contacts component 30, increasing the adhesion between distal surface 22 of stamp post 20 and component 30 in step 140. Compressing stamp post 20 by pressing it into component 30 after distal surface 22 first contacts component 30 is called overdrive and is related to the pressure exerted by stamp 10 onto component 30 by stamp 10. The overdrive can be continued, in some embodiments, until the entire distal surface 22 is in contact with component 30 as shown in FIGS. 8D-8E, further increasing adhesion between distal surface 22 and component 30. Thus, the overdrive during a pick process to remove component 30 from component source wafer 40 can be up to a distance H (the height of distal surface 22).

In some embodiments, compression can continue as shown in FIG. 8E and further compress stamp post 20 a distance greater than H possibly causing sidewalls 24 of stamp post 20 to bulge outward. The additional compression and distance allow a greater distance for stamp 10 acceleration when removing component 30 from component source wafer 40 in step 150, increasing stamp 10 speed and thereby increasing the rate-dependent adhesion between distal surface 22 and component 30. The area of distal surface 22 in contact with component 30 at the largest extent of overdrive can be a first area.

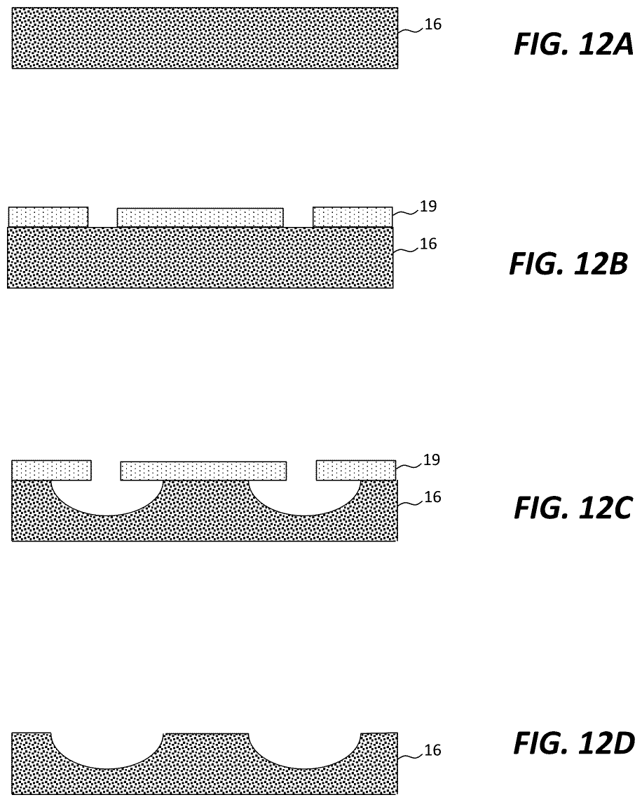

As shown in FIG. 10A, once distal surface 22 is in contact with component 30, stamp 10 is moved away from component source wafer 40 (shown in FIG. 9) to remove component 30 from component source wafer 40 and fracture (e.g., break) tether 32 or separate tether 32 from anchor 44 or component 30, thus picking component 30. Once component 30 is removed (picked) from component source wafer 40, the compression in stamp post 20 can partially relax (e.g., decompress), reducing the area of distal surface 22 in contact with component 30, thereby reducing the adhesion between component 30 and distal surface 22 as shown in FIG. 10B and step 160. The area of distal surface 22 in contact with component 30 after relaxation can be a second area less than the first (pick) area. At this stage, component 30 and stamp post 20 are in dynamic tension. Vander Waals forces keep distal surface 22 pulled into contact with component 30 at the same time that stamp post 20 compression is relaxing and pushing component 30 away from portions of distal surface 22, especially those portions that have a small radius of curvature. This dynamic tension can be controlled by controlling the stickiness of the stamp material 28 (e.g., PDMS) in stamp post 20 and by controlling the relative curvature of distal surface 22. For example, the size of any flat portion 23 can affect the area of distal surface 22 in dynamic tension. In the limit, stamp post 20 relaxes completely and only flat portion 23 is adhered to component 30 with van der Waals forces. Thus, a larger flat area of distal surface 22 can increase adhesion and a smaller flat area (in the limit a point or line) can decrease adhesion between component 30 and stamp post 20. Consequently, embodiments of the present disclosure provide a simple way to control relative adhesion between stamp post 20 and component 30, improving pick yields for micro-transfer printing with various different components 30.

Once stamp post 20 is relaxed, component 30 can be printed to a target substrate 50 provided in step 170 and shown in FIG. 10C. Component 30 and stamp 10 are aligned with target substrate 50 using the micro-transfer printer and then component 30 is contacted to target substrate 50 as shown in FIG. 10D in step 180 to adhere component 30 to target substrate 50. According to embodiments of the present disclosure, overdrive during printing in step 190 is less than overdrive during picking in step 140 and can be zero, so that the area (a third area) of distal surface 22 in contact with component 30 during printing is less than the first area of distal surface 22 in contact with component 30 during picking (since the area of convex or concave distal surface 22 in contact with component 30 depends on the overdrive and compression of stamp post 20, at least until the entire area of distal surface 22 is in contact with component 30). Thus, in embodiments, the third (print) area is less than the first (pick) area but is not less than the second (relaxed) area. The third area can be greater than the second area but, in the limit (zero overdrive), is equal to the second area. Stamp 10 is then pulled away from target substrate 50 and component 30 as shown in FIG. 10E, thereby placing stamp post 20 in tension, until stamp post 20 is no longer in contact with component 30 as shown in FIG. 10F and stamp 10 is removed and stamp post 20 relaxes, completing the printing process in step 200.

Thus, embodiments of the present disclosure provide a method for enhancing the difference in adhesion between picking and printing a component 30 during micro-transfer printing by increasing a difference in adhered area of distal surface 22 and component 30 between picking and printing, thereby increasing micro-transfer printing yields. This difference can be in addition to differences in adhesion due to rate-dependent effects (e.g., picking at a faster separation rate and printing at a slower separation rate). Furthermore, embodiments of the present disclosure provide a method for micro-transfer printing that does not require shear when printing (e.g., does not require horizontal movement of component 30 while in contact with target substrate 50). This can improve printing precision (e.g., locating component 30 more precisely where desired on target substrate 50). Furthermore, embodiments of the present disclosure can support a wider range of pick and print parameters, circumstances, or conditions because a greater range of adhesion differences between distal surface 22 and component 30 is possible at different steps in the micro-transfer printing operation. Moreover, the use of a convex or concave distal surface 22 for stamp post 20 can reduce the precision necessary to pick a component 30, for example as compared to using micro-tips since distal surface 22 changes gradually over the extent of stamp post 20 and, in case of a misalignment between stamp post 20 and component 30 a micro-tip can fail to contact component 30.

In some embodiments, an adhesive layer is provided on target substrate 50 to enhance adhesion between components 30 and target substrate 50. However, in some applications such an adhesive layer is undesirable or impractical so that printing to the target substrate 50 is more difficult. Using stamp posts 20 with a curved distal surface 22 in embodiments of the present disclosure can enable or facilitate printing to target substrate 50 without any adhesive layer since the adhesion between distal surface 22 and component 30 can be reduced using embodiments of the present disclosure.

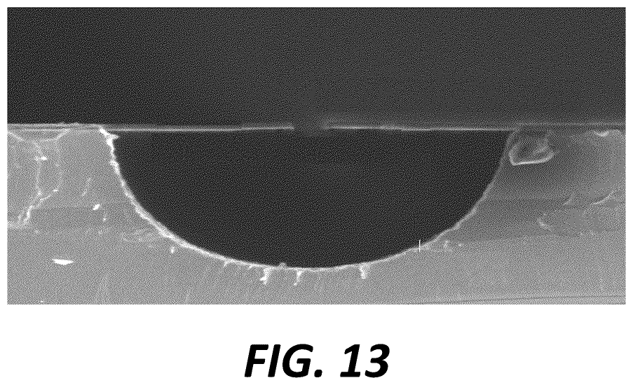

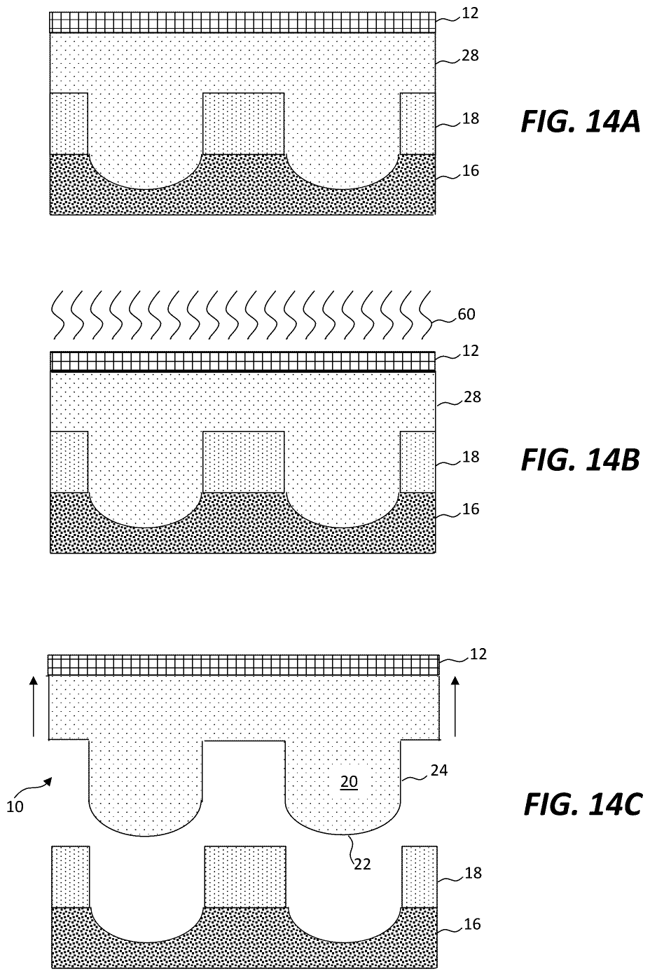

Embodiments of the present disclosure can be made in a variety of ways, for example using photolithographic methods and materials or 3D printing to make master molds from which stamps 10 can be produced. As shown in the successive cross sections of FIGS. 12A-12D and the micrograph of FIG. 13, a master wafer 16 (e.g., a mold substrate such as a silicon substrate) is provided as shown in FIG. 12A and coated with a patterned protection layer 19 (e.g., a patterned photoresist) having a hole exposing a portion of master wafer 16 (FIG. 12B). Master wafer 16 is then exposed to an etchant (e.g., XₑF₂) through the hole to etch a curved cavity or hole in master wafer 16 (FIG. 12C). The patterned protection layer 19 is then stripped (e.g., with a chemical etch) as shown in FIG. 12D. Master wafer 16 is then coated with a patternable structure material 18 as shown in FIG. 12E and then patterned to form patterned structure 18 over master wafer 16 separating the cavities as shown in FIG. 12F, completing the master mold. In some embodiments, patterned structure 18 can be coated with a thin delamination enhancement layer 17D as shown in FIG. 12G, for example, an inorganic material, such as SiO₂, or a metal sputtered or evaporated onto patterned structure 18 that is relatively thin compared to the size of structures in patterned structure 18.

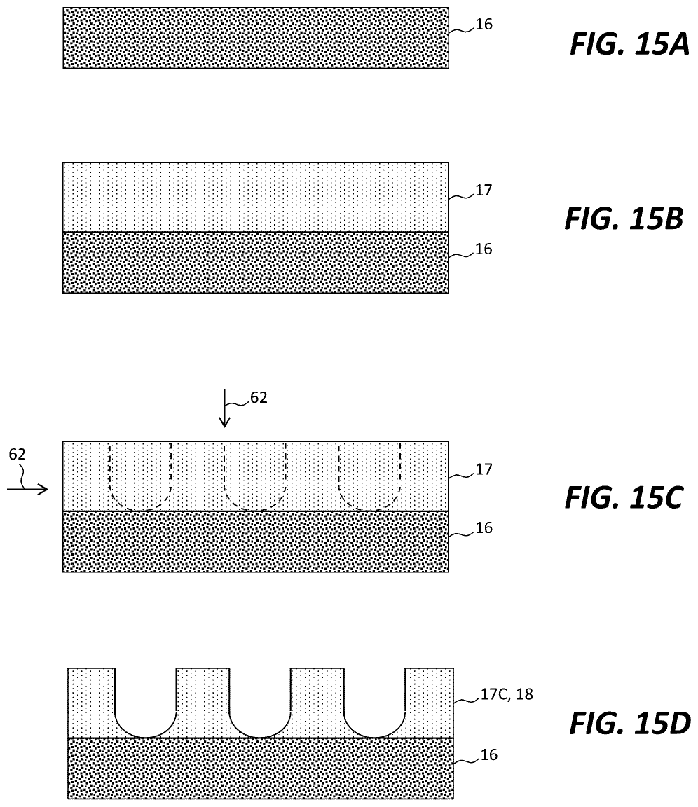

Stamps 10 having stamp posts 20 with a convex or concave distal end 22 can be constructed using the master mold. As shown in FIG. 14A, patterned structure 18 and master wafer 16 are coated with an elastic stamp material 28 (such as PDMS) against rigid support 12 and then cured, for example with heat 60 or radiation, as shown in FIG. 14B, for example for some hours (e.g., 8 hours) at an elevated temperature, for example 60° C., and then removed from the mold as shown in FIG. 14C, to provide stamp 10.

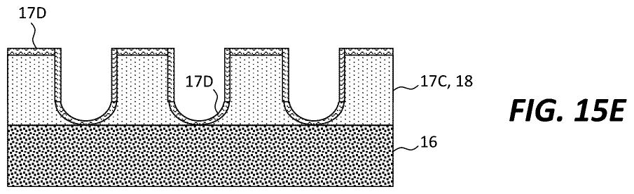

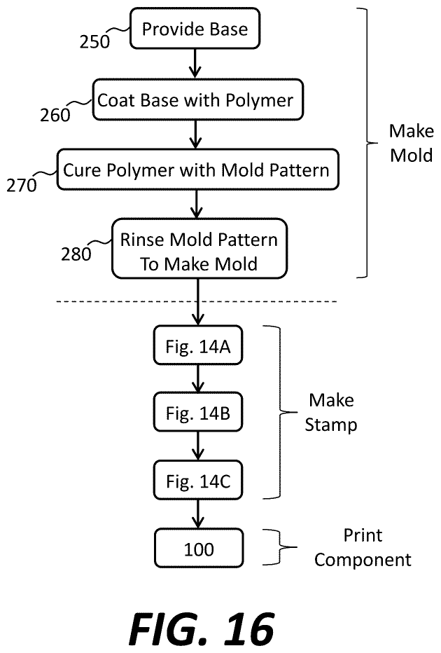

In some embodiments, a master mold (e.g., a stamp mold) can be made using 3D printing, for example using two-photon polymerization to cure a patterned structure 18 (e.g., using a polymer such as an acrylic) and cavity on a base 16 (e.g., a rigid substrate such as glass or a silicon master wafer 16), curing the patterned structure 18, and then forming stamp 10. FIGS. 15A-15D illustrate embodiments of the present disclosure according to methods illustrated in the FIG. 16 flow diagram. In step 250 and as illustrated in FIG. 15A, a base 16 (e.g., glass or a silicon master wafer 16) is provided. Base 16 is coated with a curable material 17 (e.g., a polymer, such as an acrylic) in step 260, as shown in FIG. 15B. Curable material 17 can be cured to form cured material 17C in a pattern defining a patterned structure 18 (mold), as shown in FIG. 15C, in step 270 using, for example, light 62 with two-photon polymerization, and then rinsed in step 280 as shown in FIG. 15D. Patterned structure 18 can comprise openings defining stamp posts 20 and can be coated with a thin delamination enhancement layer 17D as shown in FIG. 15E, for example, an inorganic material, such as SiO₂, or a metal sputtered or evaporated onto patterned structure 18 at a relatively lower temperature, such as 200 degrees C., for example, a lower temperature than a cure temperature of patterned structure 18, to facilitate removing or peeling a cured material disposed in the openings. Delamination enhancement layer 17D can be relatively thin compared to the size of structures in patterned structure 18. Patterned structure 18 (e.g., a mold comprising cured material 17C) can then be used to form stamp 10 as shown in FIGS. 14A-14C. The curing temperature for PDMS can be significantly lower than that for patterned structure 18 (e.g., depending on choice of material(s) for patterned structure 18), so that stamp 10 can be constructed and removed from the 3D printed mold. Stamp 10 can then be used to print components 30 from a source wafer 40 to a target substrate 50, for example as discussed in FIG. 11. Curved portions of a mold can, but do not necessarily, contact base 16. For example, curved portions can contact base 16 at a line (if one-dimensionally convex), a point (if two-dimensionally convex), or not at all (if one-dimensionally or two-dimensionally convex).

A master mold can be treated, for example fluorinated, or otherwise coated to enhance and enable the removal of stamp 10 from the master mold. Treatment or coating can be made, for example, using a liquid or a gas, by applying a solid (e.g., a solid-phase coating), or by processing one or more surfaces of a master mold (e.g., mechanically processing).

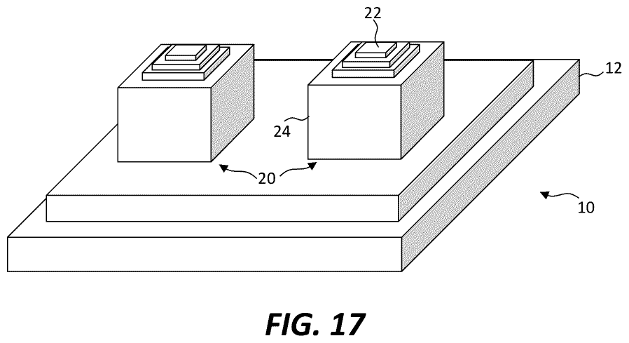

FIG. 17 illustrates embodiments of the present disclosure in which distal surface 22 of stamp post 20 has a rectangular stepped configuration forming distal surface 22 extending away from rigid support 12 in a convex configuration. In other embodiments, distal surface 22 can have a concave rectangular stepped configuration (not shown in the Figures). Such additional layers forming patterned structures 18 can be made by iteratively and photolithographically depositing precursor structure material 18 over rigid support 12 and any layers disposed on rigid support 12, exposing the precursor structure material 18 through a mask to form a next layer (e.g., another step), curing the exposed structure material 18, and then rinsing uncured structure material 18 away. The steps can be repeated to form as many layers (or steps) as desired. Stamps 10 with stamp posts 20 as shown in FIG. 17 can also be constructed using 3D printing, as described above.

Component source wafer 40 can be any suitable wafer or substrate for forming or disposing components 30, for example a semiconductor wafer. The printer can be any suitable mechanical device for locating and moving stamp 10 with respect to component source wafer 40 and target substrate 50, for example a mechatronic motion platform with optical alignment capability. Component source wafer 40 can comprise a sacrificial layer comprising sacrificial portions 42 separated by anchors 44. Each component 30 can be disposed exclusively and directly over sacrificial portion 42 so that, when sacrificial portion 42 is etched, components 30 are suspended over component source wafer 40 by tether 32.

According to some embodiments of the present disclosure, a micro-transfer-printing stamp 10 comprises components 30 disposed on distal end 22 of stamp posts 20. According to some embodiments of the present disclosure, components 30 are physically attached to anchor 44 with tether 32 exclusively and directly over sacrificial portions 42, suspended over component source wafer 40, and adhered to stamp posts 20 of stamp 10. According to some embodiments of the present disclosure, components 30 with fractured tethers 32 are disposed on and adhered to target substrate 50 and adhered to stamp posts 20 of stamp 10.

Components 30 according to embodiments of the present disclosure can be micro-components and stamp posts 20 can be correspondingly small. For example, components 30 can have a length or width no greater than 200 microns, no greater than 100 microns, no greater than 50 microns, no greater than 20 microns, no greater than 10 microns, no greater than 5 microns, or no greater than 2 microns. The thickness of components 30 can be no greater than 50 microns, no greater than 20 microns, no greater than 10 microns, no greater than 5 microns, no greater than two microns, no greater than one micron, or no greater than 0.5 microns. Stamp posts 20 can have a distal end 22 with an area similar to the area (length by width) of components 30, somewhat smaller, or somewhat larger. The area of distal end 22 (farthest from rigid support 12) can have an area no greater than the area of components 30, for example no greater than 80%, no greater than 50%, or no greater than 25% of distal end 22.

The height of stamp posts 20 can be, for example, 10-50 microns. Height H of distal surface 22 can be at least or no greater than two microns, at least or no greater than five microns, at least or no greater than ten microns, at least or no greater than fifteen microns, or at least or no greater than twenty microns. The desired height H can depend on component 30 size, the Young's modulus of stamp post 20 and stamp material 28, and the rate at which stamp 10 is moved with respect to component source wafer 40 or target substrate 50.

The positions and movements of stamps 10, component source wafer 40, and target substrate 50 can be controlled by a motion platform (e.g., a 2D or 3D motion platform controlling horizontal, vertical, and rotational movement and alignment). For example, stamp 10, component source wafer 40, and target substrate 50 can be in contact with, and their movements controlled by, the motion platform. A motion platform can be a mechatronic system that uses an optical camera to align stamp 10 to component source wafer 40, components 30, and target substrate 50. Components 30 can be integrated circuits or layers of material or other structures released (e.g., by etching) from component source wafer 40.

Mesa 14 can comprise a same stamp material 28 as stamp posts 20 and can be equally flexible (e.g., have a common Young's modulus). In some embodiments, mesa 14 comprises the same stamp material(s) 28 as stamp posts 20 but in different proportions, so that stamp posts 20 are more flexible than mesa 14. In some embodiments, mesa 14 comprises different stamp materials than stamp posts 20 and stamp posts 20 are more flexible than mesa 14 (e.g., have a lower Young's modulus). According to some embodiments, mesa 14 can comprise a common mesa 14 or comprise separate mesas 14 each supporting a subset of stamp posts 20. Rigid support 12 can be, for example, any suitable wafer or rigid structure with a substantially planar surface suitable for processing, for example glass, silicon, sapphire, or quartz. Rigid support 12 can be less flexible than mesa 14 and less flexible than stamp posts 20.

Components 30 can be native to component source wafer 40 and each component 30 can be disposed completely and entirely over sacrificial portion 42. Component source wafer 40 can comprise a sacrificial layer comprising sacrificial portions 42 laterally separated by anchors 44. Components 30 can be physically connected to anchors 44 by tethers 32. In embodiments, sacrificial portions 42 are sacrificed, for example by dry or wet etching, so that sacrificial material in sacrificial portions 42 is removed to form a gap (as shown in FIG. 9).

In certain embodiments, component source wafer 40 can be any structure with a surface suitable for forming patterned sacrificial layers having sacrificial portions 42 (or an etched gap), anchors 44, tethers 32, and disposing or forming patterned components 30. For example, component source wafers 40 can comprise a semiconductor or compound semiconductor and can comprise an etchable sacrificial layer comprising material different (e.g., an oxide) from material of component source wafer 40. Any one or more of component source wafer 40 and sacrificial portion 42 can comprise an anisotropically etchable material. Suitable semiconductor materials can be silicon or silicon with a (100) or (111) crystal structure (e.g., orientation). A surface of component source wafer 40 can be substantially planar and suitable for photolithographic processing, for example as found in the integrated circuit or MEMs art.

Component 30 can be encapsulated by an encapsulation layer to protect component 30 from environmental contaminants. The encapsulation layer can also coat portions of component source wafer 40 and anchors 44. In some embodiments, tether 32 comprises portions of an encapsulation layer or a portion of an encapsulation layer forms tether 32. Component 30 can comprise an encapsulation layer and tether 32 or a portion (e.g., fractured or separated portion) of tether 32.

In some embodiments of the present disclosure, components 30 are small integrated circuits or micro-electro-mechanical (MEMS) devices, for example chiplets (e.g., micro-chiplets). Component 30 can have any suitable aspect ratio or size in any dimension and any useful shape, for example a rectangular cross section or rectangular top or rectangular bottom surface. Components 30 can be micro-components, for example having at least one dimension that is in the micron range, for example having a planar extent from 2 microns by 5 microns to 200 microns by 500 microns (e.g., an extent of 2 microns by 5 microns, 20 microns by 50 microns, or 200 microns by 500 microns) and, optionally, a thickness of from 200 nm to 200 microns (e.g., at least or no more than 2 microns, 20 microns, or 200 microns). Components 30 can have a thin substrate with at least one of (i) a thickness of only a few microns, for example less than or equal to 25 microns, less than or equal to 15 microns, or less than or equal to 10 microns, (ii) a width of 5-1000 microns (e.g., 5-10 microns, 10-50 microns, 50-100 microns, or 100-1000 microns) and (iii) a length of 5-1000 microns (e.g., 5-10 microns, 10-50 microns, 50-100 microns, or 100-1000 microns).

Such micro-components can be made in a native source semiconductor wafer (e.g., a silicon wafer or compound semiconductor wafer such as component source wafer 10) having a process side and a back side used to handle and transport the wafer using lithographic processes. Components 30 can be formed using lithographic processes in an active layer on or in the process side of component source wafer 40. Methods of forming such structures are described, for example, in U.S. Pat. No. 8,889,485. According to some embodiments of the present disclosure, component source wafers 40 can be provided with components 30, a sacrificial layer (a release layer), sacrificial portions 42 anchors 44, and tethers 32 already formed, or they can be constructed as part of a process in accordance with certain embodiments of the present disclosure.

In certain embodiments, components 30 can be constructed using foundry fabrication processes used in the art. Layers of materials can be used, including materials such as metals, oxides, nitrides and other materials used in the integrated-circuit art. Components 30 can have different sizes, for example, less than 1000 square microns or less than 10,000 square microns, less than 100,000 square microns, or less than 1 square mm, or larger. Components 30 can have variable aspect ratios, for example at least 1:1, at least 2:1, at least 5:1, or at least 10:1. Components 30 can be rectangular or can have other shapes.

A component 30 can be an active circuit component, for example including one or more active electronic elements such as electronic transistors or diodes or light-emitting diodes or photodiodes that produce an electrical current in response to ambient light. A component 30 can be a passive component, for example including one or more passive elements such as resistors, capacitors, or conductors. In some embodiments, component 30 includes both active and passive elements. Component 30 can be a semiconductor device having one or more semiconductor layers, such as an integrated circuit. Component 30 can be an unpackaged die. In some embodiments, component 30 is a compound device having a plurality of active or passive elements, such as multiple semiconductor components with separate substrates, each with one or more active elements or passive elements, or both. Components 30 can be or include, for example, electronic processors, controllers, drivers, light-emitting diodes, photodiodes, light-control devices, light-management devices, piezoelectric devices, acoustic wave devices (e.g., acoustic wave filters), optoelectronic devices, electromechanical devices (e.g., microelectromechanical devices), photovoltaic devices, sensor devices, photonic devices, magnetic devices (e.g., memory devices), or elements thereof. A device can be or include, for example, electronic processors, controllers, drivers, light-emitting diodes, photodiodes, light-control devices, light-management devices, piezoelectric devices, acoustic wave devices (e.g., acoustic wave filters), optoelectronic devices, electromechanical devices (e.g., microelectromechanical devices), photovoltaic devices, sensor devices, photonic devices, magnetic devices (e.g., memory devices).

A transfer printer may include motion-plus-optics machinery (e.g., an opto-mechatronic motion platform) for performing print operations. For example, the transfer printer may include stamp 10 mounted onto motion-plus-optics machinery (e.g., an opto-mechatronic motion platform) in order to precisely control alignment and kinetics of with respect to a source wafer of components 30 and stamp 10. In some embodiments, during micro-transfer printing, a motion platform of a transfer printer brings stamp 10 into contact with components 30 on component source wafer 40, with optical alignment performed before contact. In some embodiments, rapid upward movement of the print-head (or, in some embodiments, downward movement of component source wafer 40) breaks (e.g., fractures) or separates component tether(s) forming broken (e.g., fractured) or separated component tethers, transferring component(s) 30 to distal surface(s) of post 20 ends of stamp 10. In some embodiments, the populated stamp 10 then travels to target substrate 50 (or vice versa) and one or more components 30 are then printed.

As is understood by those skilled in the art, the terms “over” and “under” are relative terms and can be interchanged in reference to different orientations of the layers, elements, and substrates included in the present disclosure. For example, a first layer on a second layer, in some implementations means a first layer directly on and in contact with a second layer. In other implementations, a first layer on a second layer includes a first layer and a second layer with another layer therebetween.

Having described certain implementations of embodiments, it will now become apparent to one of skill in the art that other implementations incorporating the concepts of the disclosure may be used. Therefore, the disclosure should not be limited to certain implementations, but rather should be limited only by the spirit and scope of the following claims.

Throughout the description, where apparatus and systems are described as having, including, or comprising specific elements, or where processes and methods are described as having, including, or comprising specific steps, it is contemplated that, additionally, there are apparatus, and systems of the disclosed technology that consist essentially of, or consist of, the recited components, and that there are processes and methods according to the disclosed technology that consist essentially of, or consist of, the recited processing steps.

It should be understood that the order of steps or order for performing certain action is immaterial so long as the disclosed technology remains operable. Moreover, two or more steps or actions in some circumstances can be conducted simultaneously. The disclosure has been described in detail with particular reference to certain embodiments thereof, but it will be understood that variations and modifications can be effected within the spirit and scope of the claimed invention.

### PARTS LIST

A cross section
H height
10 stamp
12 rigid support
14 mesa
16 master wafer/base
17 curable material/curable polymer
17C cured material/cured polymer/mold
17D delamination enhancement layer
18 patterned structure/structure material
19 protection layer
20 post/stamp post
22 distal end/distal surface
23 flat portion
24 sidewall
25 ring/perimeter
26 center
28 stamp material
30 component/device
32 tether
40 component source wafer/component source substrate
42 sacrificial portion
44 anchor
50 target substrate
60 heat
62 light
100 provide source wafer with component step
110 provide stamp step
120 provide printer step
130 contact stamp distal end to component step
140 overdrive stamp step
150 remove component from source wafer step
160 relax stamp post in contact with component step
170 provide target substrate step
180 contact component to target substrate step
190 less overdrive stamp step
200 remove stamp from component and target substrate step
250 provide base step
260 coat base with polymer step
270 cure polymer with mold pattern step
280 rinse mold pattern to make mold step

1. A micro-transfer-printing stamp, comprising:
a rigid support;
an array of posts disposed over the rigid support, each of the posts in the array of posts extending in a direction away from the rigid support to a distal surface of the post, wherein
(i) the distal surface is (a) convex with a center farther from the rigid support than another portion of the distal surface away from the center such that the convex distal surface is structured to contact a component when the distal surface is pressed against the component or (b) concave with a center closer to the rigid support than another portion of the distal surface away from the center such that the concave distal surface is structured to contact a component when the distal surface is pressed against the component, and
(ii) each of the posts comprises an elastic material.

2. The micro-transfer-printing stamp of claim 1, wherein each of the posts in the array of posts comprises an elastomeric material.

3. The micro-transfer-printing stamp of claim 1, wherein each of the posts in the array of posts comprises PDMS.

4. The micro-transfer-printing stamp of claim 1, wherein the distal surface of each of the posts is continuously curved.

5. The micro-transfer-printing stamp of claim 4, wherein a radius of curvature of the distal surface decreases from the center to the edge.

6. The micro-transfer-printing stamp of claim 4, wherein a radius of curvature of the distal surface is constant.

7. The micro-transfer-printing stamp of claim 1, wherein the distal surface is stepped.

8. The micro-transfer-printing stamp of claim 1, wherein a portion of the distal surface is flat.

9. The micro-transfer-printing stamp of claim 8, wherein the portion that is flat includes the center.

10. The micro-transfer-printing stamp of claim 8, wherein the portion that is flat forms a perimeter around the center.

11. The micro-transfer-printing stamp of claim 8, wherein the portion that is flat is a simple closed curve.

12. The micro-transfer-printing stamp of claim 8, wherein a portion of the distal surface that is not flat is curved and has a constant radius of curvature.

13. The micro-transfer-printing stamp of claim 8, wherein a portion of the distal surface that is not flat is curved and has a radius of curvature that decreases in a direction from the center to the edge.

14. The micro-transfer-printing stamp of claim 1, comprising a mesa disposed on the rigid support between the rigid support and the posts, wherein the posts extend from the mesa away from the rigid substrate.

15. The micro-transfer-printing stamp of claim 1, comprising a component having a component surface, wherein, for one of the posts, the post is under compression and all of the distal surface of the post is in contact with the component surface.

16. The micro-transfer-printing stamp of claim 15, comprising a component source wafer, wherein the component is connected to the component source wafer.

17. The micro-transfer-printing stamp of claim 1, comprising a component having a component surface, wherein, for one of the posts, the post is under tension or compression and all of the distal surface of the post is in contact with the component surface.

18. The micro-transfer-printing stamp of claim 1, comprising a component having a component surface, wherein the posts are under compression or tension, and less than all of the distal surface of one of the posts is in contact with the component surface.

19. The micro-transfer-printing stamp of claim 18, comprising a target substrate having a target substrate surface, wherein the component is in contact with the target substrate surface on a surface of the component opposite the component surface.

20. The micro-transfer-printing stamp of claim 1, wherein the distal surface is concave or convex in one dimension.

21. The micro-transfer-printing stamp of claim 1, wherein the distal surface is concave or convex in two dimensions.

22-45. (canceled)
